(19) United States
(12) Patent Application Publication
(10) Pub. No.: US 2025/0087620 A1
(43) Pub. Date: Mar. 13, 2025

(54) SEMICONDUCTOR DEVICE

(71) Applicant: KABUSHIKI KAISHA TOSHIBA, Tokyo (JP)

(72) Inventors: Tomoka HOSHINO, Kawaguchi Saitama (JP); Daisuke HIRATSUKA, Yokohama Kanagawa (JP)

(21) Appl. No.: 18/604,240

(22) Filed: Mar. 13, 2024

(30) Foreign Application Priority Data
Sep. 13, 2023 (JP) 2023-148761

(51) Int. Cl. H01L 23/00

(52) U.S. Cl. CPC H01L 24/29; H01L 24/32; H01L 2224/29011; H01L 2224/29124; H01L 2224/29139; H01L 2224/29144; H01L 2224/29147; H01L 2224/29155; H01L 2224/29169; H01L 2224/32245; H01L 2924/351

(57) ABSTRACT

According to one embodiment, a semiconductor device includes a metal spacer, a semiconductor chip having a metal electrode; and a bonding portion disposed between the metal spacer and the metal electrode. The bonding portion is formed of a porous metal sintered body. The metal sintered body includes first voids formed without being contained within the metal sintered body and second voids contained within the metal sintered body. A Young's modulus of the bonding portion is lower than a Young's modulus of each of the metal spacer and the metal electrode.

### CROSS-REFERENCE TO RELATED APPLICATIONS

This application is based up on and claims the benefit of priority from Japanese Patent Application No.2023-148761, filed on Sep. 13, 2023; the entire contents of which are incorporated herein by reference.

### FIELD

The embodiments of the invention relate to a semiconductor device.

### BACKGROUND

There is a member bonding method in which a metal sintered material for connection is formed in a predetermined printing pattern in a connection region of each member by printing, and the printing pattern includes a region to which the metal sintered material is applied and a region to which the metal sintered material is not applied.

There is known a semiconductor device in which a metal spacer and a semiconductor chip having a metal electrode are sintered and bonded. In the type of semiconductor device, when the metal spacer and the semiconductor chip are sintered and bonded to each other, a thermal stress may be generated due to a difference between a thermal expansion coefficient of the metal spacer and a thermal expansion coefficient of the semiconductor chip, and a bonding portion and the metal electrode may be deformed. In particular, when a Young's modulus of the bonding portion is larger than that of the metal electrode, there is a risk that the thermal stress is concentrated on the metal electrode of the semiconductor chip and the metal electrode is deformed and broken, and therefore, prevention of deformation of the metal electrode is an issue.

### BRIEF DESCRIPTION OF THE DRAWINGS

FIG. 1 is a cross-sectional view showing an example of a configuration of a semiconductor device;

FIG. 2 is a top view showing an example of a shape of the first void provided in a bonding portion formed on a metal spacer;

FIG. 3 is a cross-sectional view showing an example of the A-A cross section in FIG. 2

FIG. 4 is a diagram showing an example of an enlarged region W in FIGS. 2 and 3;

FIG. 5 is a diagram showing an example of a range of void ratio where thermal stress can be reduced, in the case where the parent phase metal of the metal sintered body is Ag and the metal electrode of the semiconductor chip is Al;

FIG. 6 is a diagram showing an example of a range of void ratio in which an increase in a thermal resistance of bonding portions can be prevented, in the case where the parent phase metal of the metal sintered body is Ag and the metal electrode of the semiconductor chip is Al;

FIG. 7 is a diagram showing an example of a range of void ratio in which thermal stress generated in metal electrode portions can be reduced and an increase in thermal resistance of bonding portions can be prevented, in the case where the parent phase metal of the metal sintered body is Ag and the metal electrode of the semiconductor chip is Al;

FIG. 8 is a diagram showing an example of a range of void ratio where thermal stress can be reduced, in the case where the parent phase metal of the metal sintered body is Cu and the metal electrode of the semiconductor chip is Al in which a thermal stress generated in metal electrode portions can be reduced;

FIG. 9 is a diagram showing an example of a range of void ratio in which an increase in thermal resistance of bonding portions can be prevented, in the case where the parent phase metal of the metal sintered body is Cu and the metal electrode of the semiconductor chip is Al;

FIG. 10 is a diagram showing an example of a range of void ratio in which thermal stress generated in metal electrode portions can be reduced and an increase in thermal resistance of bonding portions can be prevented, in the case where the parent phase metal of the metal sintered body is Cu and the metal electrode of the semiconductor chip is Al;

FIG. 11 is a top view showing a case where the radius is changed depending on the position of the first void.;

FIG. 12 is a top view showing a case in which the radius of first voids of bonding portion is the same but a distribution is changed;

FIG. 13 is a top view showing a case where it has a region with a changed radius as shown in FIG. 11, and a region with the same radius as shown in FIG. 12 but with a changed distribution.;

FIG. 14 is a top view showing an example of a case in which first voids are disposed in a houndstooth pattern;

FIGS. 15 to 17 are top views which correspond to FIGS. 11 to 13, in the case where the first void is arranged in a houndstooth pattern;

FIG. 18 is a top view showing an example of a case in which hexagonal first voids are disposed in bonding portion in a houndstooth pattern; and

FIG. 19 is a top view showing an example of bonding portions each including multiple circular metal sintered bodies disposed in a houndstooth pattern.

### DETAILED DESCRIPTION

Embodiments of the invention provide a semiconductor device capable of preventing deformation of a metal electrode of a semiconductor chip during generation of a thermal stress, with respect to a metal spacer and a semiconductor chip having a metal electrode connected to the metal spacer through a metal sintered body.

According to one embodiment, a semiconductor device includes a metal spacer, a semiconductor chip having a metal electrode; and a bonding portion disposed between the metal spacer and the metal electrode. The bonding portion is formed of a porous metal sintered body. The metal sintered body includes first voids formed without being contained within the metal sintered body and second voids contained within the metal sintered body. A Young's modulus of the bonding portion is lower than a Young's modulus of each of the metal spacer and the metal electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

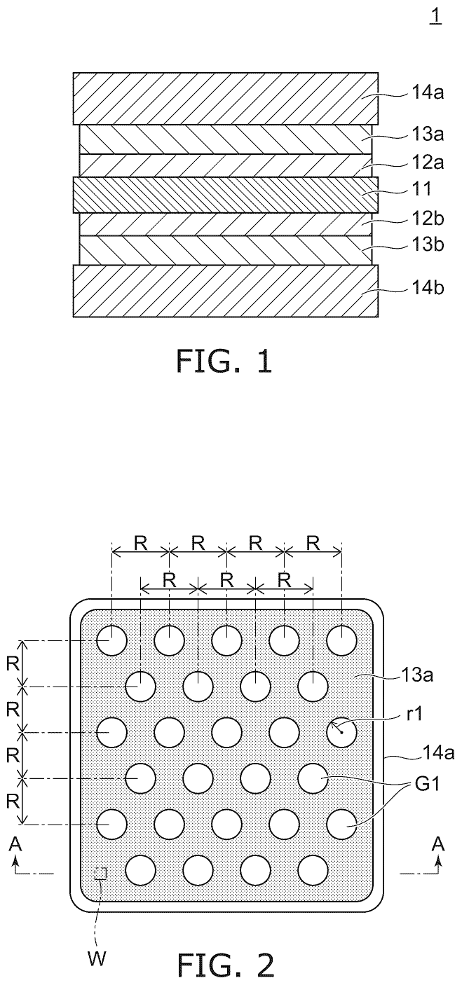

FIG. 1 is a cross-sectional view showing an example of a configuration of a semiconductor device 1.

As shown in FIG. 1, in the semiconductor device 1, a metal electrode portion 12a, a bonding portion 13a, and a metal spacer 14a are provided in this order on an upper side of a semiconductor chip 11. A metal electrode portion 12b, a bonding portion 13b, and a metal spacer 14b are provided in this order on a lower side of the semiconductor chip 11. The metal electrode portions 12a and 12b, the bonding portions 13a and 13b, and the metal spacers 14a and 14b are made of the same material.

In the semiconductor device 1, the metal electrode portions 12a and 12b and the metal spacers 14a and 14b are respectively sintered and bonded through the bonding portions 13a and 13b.

A material of the semiconductor chip 11 is, for example, silicon (Si). A thermal expansion coefficient of the semiconductor chip 11 is, for example, 2.6×10⁻⁶ [/K]. A material of the metal electrode portions 12a and 12b is, for example, aluminum (Al). In the embodiment, aluminum is described as an example, and an aluminum alloy containing aluminum may be used. The metal electrode portions 12a and 12b may be implemented to be connected to the semiconductor chip 11 via nickel gold or nickel silver. A thermal expansion coefficient of the metal electrode portions 12a and 12b is, for example, 23.9×10⁻⁶ [/K]. The bonding portions 13a and 13b are porous metal sintered bodies disposed between the metal electrode portions 12a and 12b and the metal spacers 14a and 14b. In the embodiment, a metal species of the metal sintered body forming the bonding portions 13a and 13b is, for example, silver (Ag), and a thermal expansion coefficient thereof is 19.7×10⁻⁶ [/K]. A material of the metal spacers 14a and 14b is, for example, molybdenum (Mo). A thermal expansion coefficient of the metal spacers 14a and 14b is 4.8×10⁻⁶ [/K].

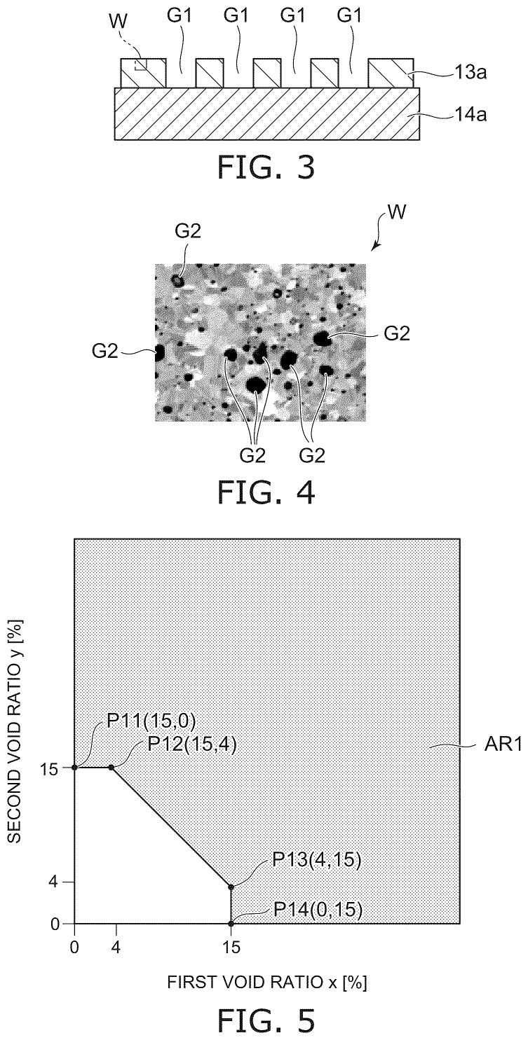

FIG. 2 is a top view showing an example of a shape of the bonding portion 13a formed on the metal spacer 14a. FIG. 3 is a cross-sectional view showing an example of an A-A cross section of FIG. 2. In the embodiment, the semiconductor device 1 has a rectangular shape in a top view. A region W shows a partial region of the bonding portion 13a.

As shown in FIGS. 2 and 3, the bonding portion 13a is disposed on the metal spacer 14a. In the bonding portion 13a, multiple first voids G1 are provided in the top view. In the embodiment, the first void G1 has, for example, a circular shape in the top view. The first voids G1 are formed between the metal electrode portion 12a and the metal spacer 14a and between the metal electrode portion 12b and the metal spacer 14b. A radius of the first void G1 is, for example, a radius r1. The multiple first voids G1 are disposed at intervals R. Between an even-numbered column and an odd-numbered column, the interval between the multiple first voids G1 is disposed by being shifted by R/2 (half). In addition, between an even-numbered row and an odd-numbered row, the interval between the multiple first voids G1 is a diameter R of G1. In this way, the first voids G1 are disposed in a houndstooth pattern in the bonding portion 13a in the top view. 35

FIG. 4 is a diagram showing an example of the enlarged region W in FIGS. 2 and 3. As shown in FIG. 4, multiple second voids G2 are provided. The second void G2 is a void contained within the bonding portion 13a. A ratio of the second voids G2 in the bonding portion 13a is determined by, for example, the material of the bonding portion 13a, a shape and a dimension of the bonding portion 13a, and a process during sintering and bonding. The second void G2 is a fairly small void compared to the first void G1. In other words, the first void G1 is a macro void, and the second void G2 is a micro void. The first void G1 is, for example, a circular hole having a diameter of 0.1 mm or more in a top view, and the second void G2 is, for example, a space having a diameter of approximately 1 to 10 μm. The second voids G2 are generated to be scattered in the bonding portion 13a during the process of sintering and bonding. Similarly to the region W, a portion of the bonding portion 13a other than the region W and the bonding portion 13b also include the second void G2 during sintering and bonding.

Next, a method for preventing deformation of the metal electrode portions 12a and 12b due to a thermal stress generated between the semiconductor chip 11 and the metal spacers 14a and 14b in the semiconductor device 1 will be described.

In the semiconductor device 1, in order to reduce the thermal stress generated in the metal electrode portions 12a and 12b, a Young's modulus of the bonding portions 13a and 13b is set to be not more than a Young's modulus of the metal electrode portions 12a and 12b. Here, the Young's modulus is E=σ/ε (E: Young's modulus, σ: stress, ε: strain). In the embodiment, since the metal electrode portions 12a and 12b are made of aluminum, the Young's modulus of the bonding portions 13a and 13b is not more than the Young's modulus of aluminum. In order to implement this, the multiple first voids G1 and the multiple second voids G2 described above are provided in the bonding portions 13a and 13b.

FIG. 5 is a diagram showing an example of a range of void ratio in which the thermal stress generated in the metal electrode portions 12a and 12b can be reduced. A vertical axis shows a second void ratio y indicating the ratio of the second voids G2 in the bonding portions 13a and 13b, and a horizontal axis shows a first void ratio x indicating the ratio of the first voids G1 in the bonding portions 13a and 13b.

Here, when E_{W} is the Young's modulus of the region W that is a part of the bonding portions 13a and 13b that does not include the first void G1 and includes only the second void G2, E_{Ag} is the Young's modulus of silver, Ebonding portion is the Young's modulus of the bonding portions 13a and 13b, and E_{Al} is the Young's modulus of aluminum, a range satisfying E_{bonding portion}≤E_{Al} satisfies the following formulas (1) and (2). The Young's modulus of a region, other than the region W, that does not include the first void G1 and includes only the second void G2 is the same as E_{W}.

$${E}_{W} = {E}_{Ag} ( 1 - y ) \qquad ( 1 )$$

$${E}_{bonding portion} = {E}_{W} ( 1 - x ) = {E}_{Ag} ( 1 - x ) ( 1 - y ) \qquad ( 2 )$$

The range that satisfies the formulas (1) and (2) is a region AR1 in FIG. 5. The region AR1 is a region above a figure connecting a position P11 (15,0), a position P12 (15,4), a position P13 (4,15), and a position P14 (0,15). Since the first void G1 and the second void G2 are provided in the bonding portions 13a and 13b such that the first void ratio x and the second void ratio y are within the region AR1, the Young's modulus of the bonding portions 13a and 13b is not more than the Young's modulus of aluminum (the metal electrode portions 12a and 12b). Therefore, the thermal stress generated in the metal electrode portions 12a and 12b decreases, and the deformation is prevented.

Next, a method for preventing an increase in thermal resistance caused by providing a void in the bonding portions 13a and 13b of the semiconductor device 1 will be described.

In the semiconductor device 1, in order to reduce the thermal resistance of the bonding portions 13a and 13b, a thermal conductivity of the bonding portions 13a and 13b is set to a predetermined value or more. For example, in the embodiment, the thermal conductivity of the bonding portions 13a and 13b is 200 W/mK or more. The thermal conductivity of 200 W/mK is about four times the thermal conductivity of solder. A value of the thermal conductivity is not limited thereto.

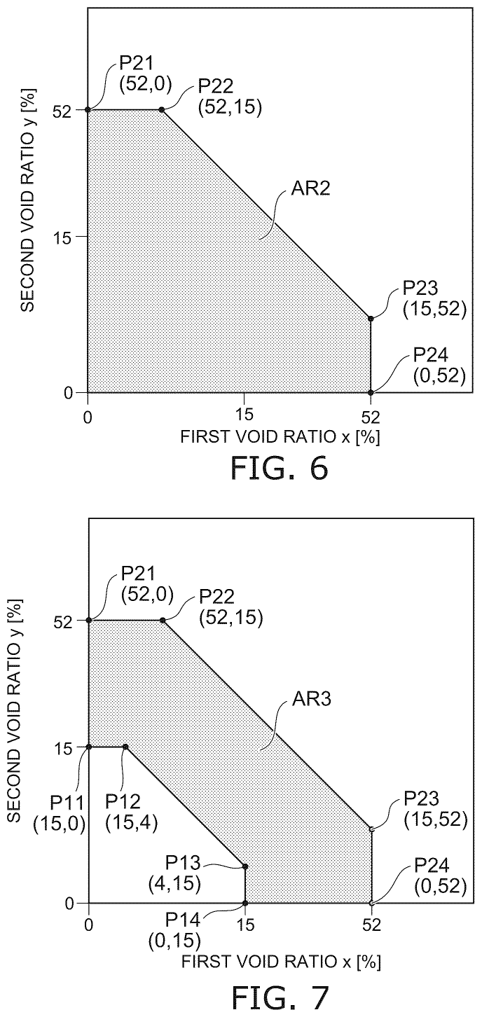

FIG. 6 is a diagram showing an example of a range of void ratio in which an increase in the thermal resistance of the bonding portions 13a and 13b can be prevented. In order to increase the thermal resistance of the bonding portions 13a and 13b due to introduction of the voids, it is desired to define a ratio of voids within a range that does not significantly reduce the apparent thermal conductivity of the bonding portions 13a and 13b including the voids. As in the case of FIG. 5, a vertical axis shows the second void ratio y indicating the ratio of the second voids G2 in the bonding portions 13a and 13b, and a horizontal axis shows the first void ratio x indicating the ratio of the first voids G1 in the bonding portions 13a and 13b.

Here, when λ_{W} is the thermal conductivity of the region W that is part of the bonding portions 13a and 13b that does not include the first void G1 and only includes the second void G2, λ_{Ag} is the thermal conductivity of silver, and λ_{bonding portion} is the thermal conductivity of the bonding portions 13a and 13b, a range satisfying λ_{bonding portion}≥200 W/mk is a range that satisfies the following formulas (3) and (4). The thermal conductivity of a region, other than the region W, that does not include the first void G1 and includes only the second void G2 is the same as λ_{W}.

$${λ}_{W} = {λ}_{Ag} ( 1 - y ) \qquad ( 3 )$$

$${λ}_{bonding portion} = {λ}_{W} ( 1 - x ) = {λ}_{Ag} ( 1 - x ) ( 1 - y ) \qquad ( 4 )$$

The range that satisfies the formulas (3) and (4) is a region AR2 in FIG. 6. The region AR2 is a region below a figure connecting a position P21 (52,0), a position P22 (52,15), a position P23 (15,52), and a position P24 (0,52). Since the first void G1 and the second void G2 are provided in the bonding portions 13a and 13b such that the first void ratio x and the second void ratio y are within the region AR2, the thermal conductivity of the bonding portions 13a and 13b is 200 W/mk or more, and an increase in the thermal resistance of the bonding portions 13a and 13b is prevented.

FIG. 7 is a diagram showing an example of a range of void ratio in which the thermal stress generated in the metal electrode portions 12a and 12b can be reduced and the increase in the thermal resistance of the bonding portions 13a and 13b can be prevented. In other words, FIG. 7 is a diagram obtained by combining FIG. 5 and FIG. 6.

As shown in FIG. 7, the range of void ratio in which the thermal stress is reduced and the increase in the thermal resistance can be prevented is a region AR3. The region AR3 is a region surrounded by the position P11 (15,0), the position P12 (15,4), the position P13 (4,15), the position P14 (0,15), the position P21 (52,0), the position P22 (52,15), the position P23 (15,52), and the position P24 (0,52).

Next, a process of forming the bonding portions 13a and 13b will be described. As a method for forming a metal sintered material on the metal spacers 14a and 14b, for example, the metal sintered material may be applied onto the metal spacers 14a and 14b by squeegee printing. The squeegee printing is a printing method in which a screen plate is pressed against the metal spacers 14a and 14b and a paste-like metal sintered material applied to the screen plate is scraped off. For example, the metal sintered material may be supplied by a jet dispenser. Further, for example, a sheet-shaped metal sintered material may be transferred onto the metal spacers 14a and 14b. In this case, the first void G1 is provided in advance in the sheet-shaped metal sintered material.

Next, the metal electrode portions 12a and 12b and the metal spacers 14a and 14b are sintered and bonded. In the process of sintering and bonding, the bonding portions 13a and 13b are formed. With the formation of the bonding portions 13a and 13b, the first void G1 and the second void G2 appear at the ratio of the region AR3 shown in FIG. 7. Accordingly, the Young's modulus of the bonding portions 13a and 13b are not more than those of the metal electrode portions 12a and 12b and the metal spacers 14a and 14b. Therefore, it is possible to prevent deformation of the metal electrode portions 12a and 12b due to the reduction of the thermal stress generated in the metal electrode portions 12a and 12b, and the increase in the thermal resistance of the bonding portions 13a and 13b.

### Second Embodiment

A second embodiment is different from the first embodiment in that copper (Cu) is used as the metal species of the metal sintered body forming the bonding portions 13a and 13b. Hereinafter, differences due to the use of copper as the material of the bonding portions 13a and 13b will be described in detail. Components same as those of the first embodiment are denoted by the same reference numerals, and a detailed description thereof is omitted.

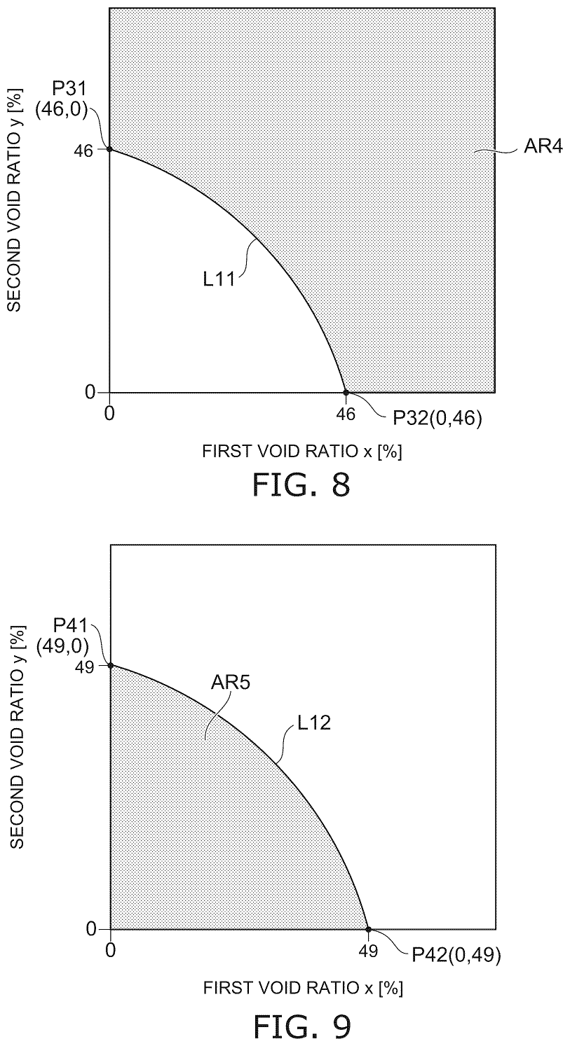

FIG. 8 is a diagram showing an example of a range of void ratio in which a thermal stress generated in the metal electrode portions 12a and 12b can be reduced. A vertical axis shows the second void ratio y indicating the ratio of the second voids G2 in the bonding portions 13a and 13b, and a horizontal axis shows the first void ratio x indicating the ratio of the first voids G1 in the bonding portions 13a and 13b.

Here, when E_{W} is the Young's modulus of the region W that is a part of the bonding portions 13a and 13b that does not include the first void G1 and includes only the second void G2, E_{Cu} is the Young's modulus of copper, E_{bonding portion} is the Young's modulus of the bonding portions 13a and 13b, and E_{Al} is the Young's modulus of aluminum, a range satisfying E_{bonding portion}≤E_{Al} satisfies the following formulas (5) and (6). The Young's modulus of a region, other than the region W, that does not include the first void G1 and includes only the second void G2 is the same as E_{W}.

$${E}_{W} = {E}_{Cu} ( 1 - y ) \qquad ( 5 )$$

$${E}_{bonding portion} = {E}_{W} ( 1 - x ) = {E}_{Cu} ( 1 - x ) ( 1 - y ) \qquad ( 6 )$$

The range that satisfies the formulas (5) and (6) is a region AR4 in FIG. 8. The region AR4 is a region above a figure L11 connecting a position P31 (46,0) and a position P32 (0,46). Since the first void G1 and the second void G2 are provided in the bonding portions 13a and 13b such that the first void ratio x and the second void ratio y are within the region AR4, the Young's modulus of the bonding portions 13a and 13b is not more than the Young's modulus of aluminum (the metal electrode portions 12a and 12b). Therefore, the thermal stress generated in the metal electrode portions 12a and 12b decreases, and the deformation is prevented.

FIG. 9 is a diagram showing an example of a range of void ratio in which an increase in the thermal resistance of the bonding portions 13a and 13b can be prevented. As in the case of FIG. 8, a vertical axis shows the second void ratio y indicating the ratio of the second voids G2 in the bonding portions 13a and 13b, and a horizontal axis shows the first void ratio x indicating the ratio of the first voids G1 in the bonding portions 13a and 13b.

Here, when λ_{W} is the thermal conductivity of the region W that is part of the bonding portions 13a and 13b that does not include the first void G1 and only includes the second void G2, λ_{Cu} is the thermal conductivity of copper, and λ_{bonding portion} is the thermal conductivity of the bonding portions 13a and 13b, a range satisfying λ_{bonding portion}≥200 W/mK is a region AR5 in FIG. 9 that satisfies the following formulas (7) and (8). The same applies to a region, other than the region W, that does not include the first void G1 and includes only the second void G2.

$${λ}_{W} = {λ}_{Cu} ( 1 - y ) \qquad ( 7 )$$

$${λ}_{bonding portion} = {λ}_{W} ( 1 - x ) = {λ}_{Cu} ( 1 - x ) ( 1 - y ) \qquad ( 8 )$$

The range that satisfies the formulas (7) and (8) is a region AR5 in FIG. 9. The region AR5 is a region below a figure L12 connecting a position P41 (49,0) and a position P42 (0,49). Since the first void G1 and the second void G2 are provided in the bonding portions 13a and 13b such that the first void ratio x and the second void ratio y are within the region AR5, the thermal conductivity of the bonding portions 13a and 13b is 200 W/mk or more, and an increase in thermal resistance of the bonding portions 13a and 13b is prevented.

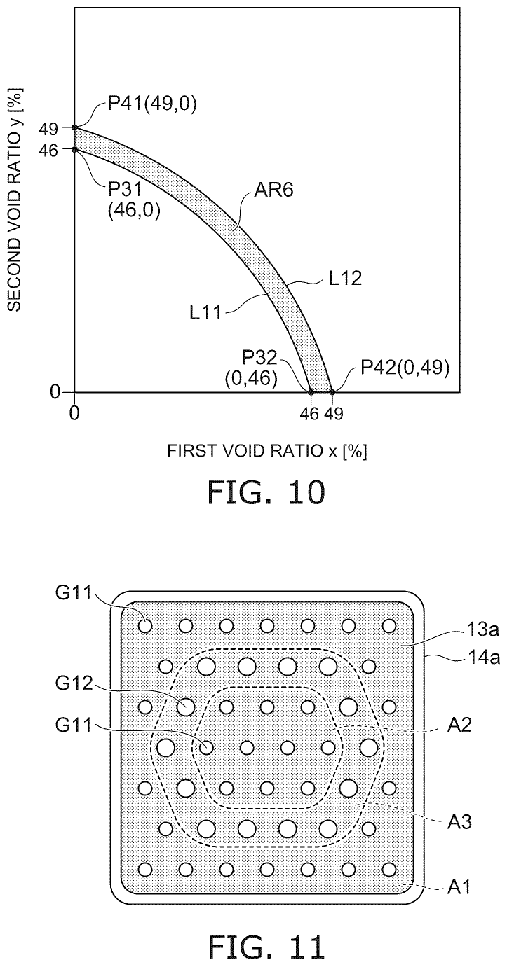

FIG. 10 is a diagram showing an example of a range of void ratio in which the thermal stress generated in the metal electrode portions 12a and 12b can be reduced and the increase in the thermal resistance of the bonding portions 13a and 13b can be prevented. In other words, FIG. 10 is a diagram obtained by combining FIG. 8 and FIG. 9.

As shown in FIG. 10, the range of void ratio in which the thermal stress is reduced and the increase in the thermal resistance can be prevented is a region AR6. The region AR6 is a region surrounded by the curve L11 connecting the position P31 (46,0) and the position P32 (0,46) and the curve L12 connecting the position P41 (49,0) and the position P42 (0,49).

Since the first void G1 and the second void G2 are provided in the bonding portions 13a and 13b such that the first void ratio x and the second void ratio y are within the region AR6, the Young's modulus of the bonding portions 13a and 13b is not more than those of the metal electrode portions 12a and 12b and the metal spacers 14a and 14b. Therefore, it is possible to prevent deformation of the metal electrode portions 12a and 12b due to the reduction of the thermal stress generated in the metal electrode portions 12a and 12b, and the increase in the thermal resistance of the bonding portions 13a and 13b. When copper is used as the material of the bonding portions 13a and 13b as described above, the effects same as those of the first embodiment can be obtained.

### Variation

Next, a variation of the bonding portions 13a and 13b formed on the metal spacers 14a and 14b will be described.

FIGS. 11 to 13 are top views showing the variation of a shape of the first voids of the bonding portions 13a and 13b. In FIGS. 11 to 13, a sheet-shaped metal sintered material is transferred onto the metal spacers 14a and 14b, and the metal spacers 14a and 14b are sintered and bonded to the metal electrode portions 12a and 12b, thereby forming the bonding portions 13a and 13b. Since the bonding portions 13a and 13b have the same configuration, the bonding portion 13a will be described as an example.

FIG. 11 is a top view showing a case in which the radius of the first void is changed. The radius of first voids G11 formed in an end A1 and a central portion A2 of the metal spacer 14a, and the radius of first voids G12 formed in an intermediate portion A3 formed between the end A1 and the central portion A2 are changed. The end A1 and the central portion A2 are regions where stress and heat are more likely to be concentrated than the intermediate portion A3. In the embodiment, the first void G11 is smaller than the first void G12. In other words, the first void G12 is larger than the first void G11.

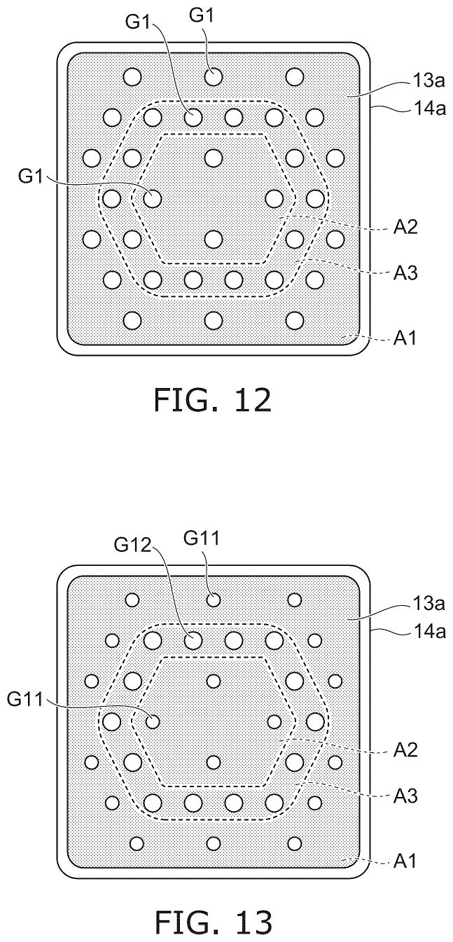

FIG. 12 is a top view showing a case in which the radius of the first voids G1 of the bonding portion 13a is the same but the distribution is changed. As shown in FIG. 12, a first distribution of the first voids G1 formed in the end A1 and the central portion A2, and a second distribution of the first voids G1 formed in the intermediate portion A3 formed between the end A1 and the central portion A2 are changed. The end A1 and the central portion A2 are regions where stress and heat are more likely to be concentrated than the intermediate portion A3. In the embodiment, the first distribution in the end A1 and the central portion A2 is sparser than the second distribution in the intermediate portion A3, and the ratio of the first voids G1 is reduced.

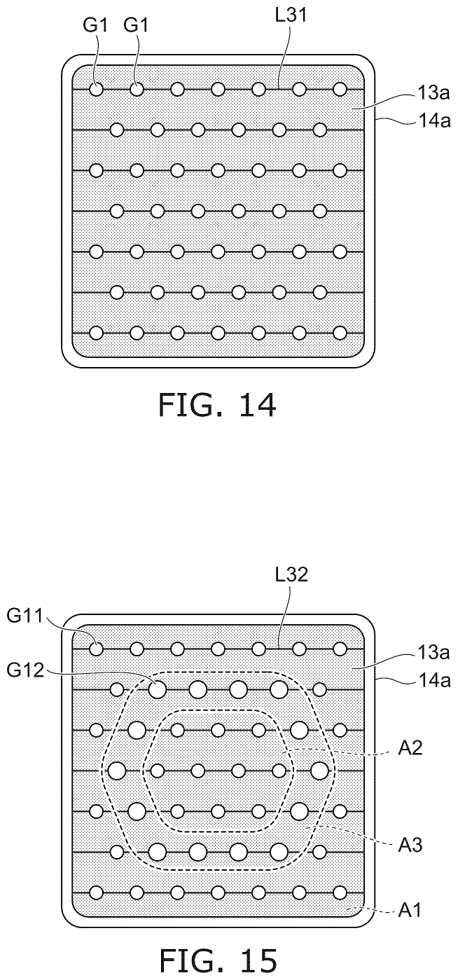

FIG. 13 is a top view showing a case in which the radius of the first voids is changed for each of the first distribution and the second distribution in addition to having the first distribution and the second distribution shown in FIG. 12. In the embodiment, the radius of the first void G11 formed in the end A1 and the central portion A2 and the radius of the first void G12 formed in the intermediate portion A3 are changed. The end A1 and the central portion A2 are regions where stress and heat are more likely to be concentrated than the intermediate portion A3. A size of the first void G11 in the first distribution is made smaller than that of the first void G12 in the second distribution. In other words, the first voids G11 in the end A1 and the central portion A2 where the stress and the heat are likely to concentrate are smaller in size than the first voids G12.

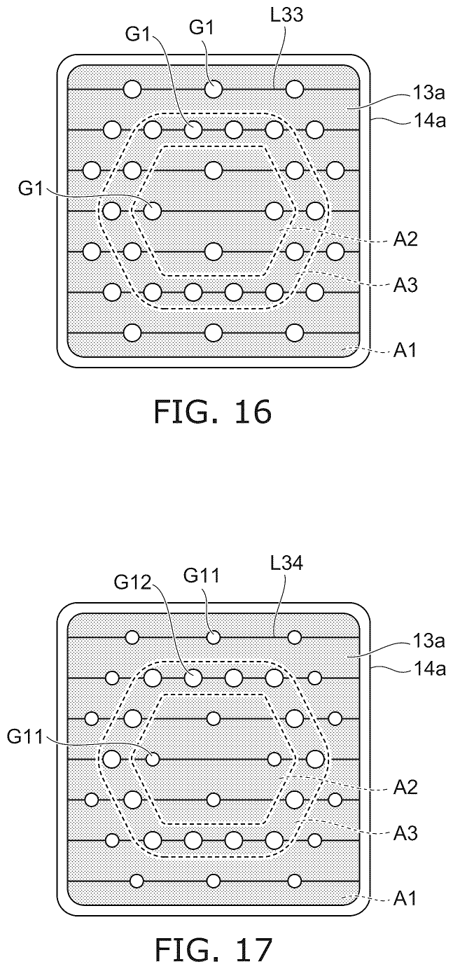

FIGS. 14 to 17 are top views showing the variation of the shape of the first voids of the bonding portions 13a and 13b. In FIGS. 14 to 17, a paste-like metal sintered material is applied onto the metal spacers 14a and 14b, and the metal spacers 14a and 14b are sintered and bonded to the metal electrode portions 12a and 12b, thereby forming the bonding portions 13a and 13b. Since the bonding portions 13a and 13b are the same, the bonding portion 13a and the metal spacer 14a will be described as an example.

FIG. 14 is a top view showing an example of a case in which the first voids are disposed in a houndstooth pattern. In FIG. 14, the number of the first voids G1 is different from the example of the bonding portion 13a shown in FIG. 2. Since a paste-like sintered member is used, a line L31 in which the first voids G1 in each row are connected in a lateral direction in the drawing is formed. FIGS. 15 to 17 correspond to FIGS. 11 to 13 described above. In FIGS. 15 to 17 as well, lines L32, L33, and L34 in which the first voids G1 (G11 and G12) in each row are connected in the lateral direction in the drawing are provided.

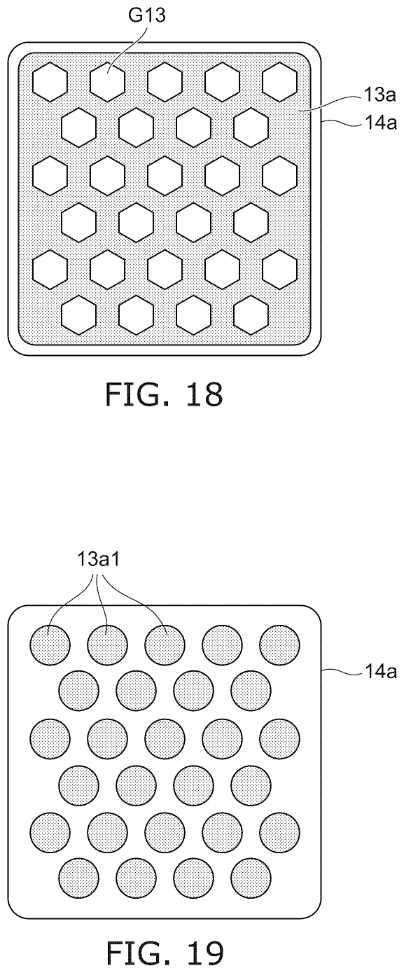

In the above-described embodiments, the case in which the shape of the first void G1 in a top view is a circular shape is described, and the disclosure is not limited thereto. For example, the shape of the first void G1 in a top view may be a polygonal shape. The polygonal shape may be, for example, a triangular shape, a quadrangular shape, and a hexagonal shape, and the larger the number of angles, the more favorable. FIG. 18 is a top view showing an example of a case in which hexagonal first voids G13 are disposed in the bonding portion 13a in a houndstooth pattern.

As shown in FIGS. 11 to 18, by forming the bonding portions 13a and 13b, and by providing the first voids G1 (or G11, G12, and G13) and the second voids G2 of the bonding portions 13a and 13b, it is possible to reduce a thermal stress generated in the metal electrode portions 12a and 12b and to prevent an increase in thermal resistance of the bonding portions 13a and 13b in the semiconductor device 1.

In the bonding portions 13a and 13b shown in FIGS. 11 to 18, the first voids G1 and the metal sintered material may be reversed. That is, the bonding portion is provided in the portion of the first void G1, and the other portion is a void. FIG. 19 is a top view showing an example of the bonding portions 13a and 13b each including multiple circular metal sintered bodies 13a1 disposed in a houndstooth pattern. As described above, the first void G1 (a region outside the metal sintered bodies 13a1) and the second void G2 are formed in the bonding portions 13a and 13b by the multiple metal sintered bodies 13a1, and it is possible to reduce a thermal stress generated in the metal electrode portions 12a and 12b and to prevent an increase in thermal resistance of the bonding portions 13a and 13b. In the case in which the bonding portions 13a and 13b are formed as described above, the effects same as those of the first embodiment can also be achieved.

In the first embodiment, silver is used as the material of the bonding portions 13a and 13b, and in the second embodiment, copper is used as the material of the bonding portions 13a and 13b, and the material of the bonding portions 13a and 13b is not limited thereto. For example, gold (Au), nickel (Ni), aluminum (Al), or platinum (Pt) may be used. That is, any one of silver, copper, gold, nickel, aluminum, and platinum may be contained as the material of the bonding portions 13a and 13b.

The Young's modulus differs depending on a type of a metal. Therefore, when a metal having a Young's modulus higher than that of silver is used as the bonding portions 13a and 13b, the ratio of the first voids G1 and the second voids G2 is larger than a case in which silver is used. In addition, when a metal having a Young's modulus lower than that of silver is used as the bonding portions 13a and 13b, the ratio of the first voids G1 and the second voids G2 is smaller than a case in which silver is used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

Embodiments may include the following configurations (e.g., technological proposals).

### Configuration 1

A semiconductor device comprising:
a metal spacer; a semiconductor chip having a metal electrode; and
a bonding portion disposed between the metal spacer and the metal electrode,
the bonding portion being formed of a porous metal sintered body,
the metal sintered body including first voids formed without being contained within the metal sintered body and second voids contained within the metal sintered body, and
a Young's modulus of the bonding portion being lower than a Young's modulus of each of the metal spacer and the metal electrode.

### Configuration 2

The device according to Configuration 1, wherein
the Young's modulus of the bonding portion is determined by a Young's modulus of a metal bulk forming the metal sintered body and a ratio of the first voids and the second voids.

### Configuration 3

The device according to Configurations 1 or 2, wherein
a ratio x of the first voids and a ratio y of the second voids satisfy the following formula,

$${E}_{bonding portion} = {E}_{metal} ( 1 - x ) ( 1 - y ) \leq {E}_{electrode} ,$$

the E_{bonding portion} being the Young's modulus of the bonding portion,
the Eₘₑₜₐₗ being a Young's modulus of a metal bulk forming the metal sintered body, and
the E_{electrode} being the Young's modulus of the metal electrode.

### Configuration 4

The device according to one of Configurations 1-3, wherein
a thermal conductivity of the bonding portion is higher than 200 W/mk and is determined by thermal conductivity of a metal forming the metal sintered body and a ratio of the first voids and the second voids.

### Configuration 5

The device according to one of Configurations 1-4, wherein
a ratio x of the first voids and a ratio y of the second voids satisfy the following formula,

$${λ}_{bonding portion} = {λ}_{metal} ( 1 - x ) ( 1 - y ) \geq 200 ,$$

the λ_{bonding portion} being a thermal conductivity of the bonding portion, and
the λₘₑₜₐₗ being a thermal conductivity of a metal bulk forming the metal sintered body.

### Configuration 6

The device according to one of Configurations 1-5, wherein
the first voids are disposed in a houndstooth pattern in the bonding portion, and
a ratio of the first voids is reduced in a region where stress and heat are concentrated in the bonding portion.

### Configuration 7

The device according to one of Configurations 1-6, wherein
the first void has a circular shape or a polygonal shape in a top view.

### Configuration 8

The device according to one of Configurations 1-7, wherein
a dimension of the first void is reduced in a region where stress and heat are concentrated in the bonding portion.

### Configuration 9

The device according to one of Configurations 1-8, wherein
the bonding portion contains any metal of Ag, Cu, Au, Ni, Al, and Pt.

What is claimed is:

1. A semiconductor device comprising:
a metal spacer;
a semiconductor chip having a metal electrode; and
a bonding portion disposed between the metal spacer and the metal electrode,
the bonding portion being formed of a porous metal sintered body,
the metal sintered body including first voids formed without being contained within the metal sintered body and second voids contained within the metal sintered body, and
a Young's modulus of the bonding portion being lower than a Young's modulus of each of the metal spacer and the metal electrode.

2. The device according to claim 1, wherein
the Young's modulus of the bonding portion is determined by a Young's modulus of a metal bulk forming the metal sintered body and a ratio of the first voids and the second voids.

3. The device according to claim 1, wherein
a ratio x of the first voids and a ratio y of the second voids satisfy the following formula,
$${E}_{bonding portion} = {E}_{metal} ( 1 - x ) ( 1 - y ) \leq {E}_{electrode} ,$$
the E_{bonding portion} being the Young's modulus of the bonding portion,
the Eₘₑₜₐₗ being a Young's modulus of a metal bulk forming the metal sintered body, and
the E_{electrode} being the Young's modulus of the metal electrode.

4. The device according to claim 1, wherein
a thermal conductivity of the bonding portion is higher than 200 W/mk and is determined by thermal conductivity of a metal forming the metal sintered body and a ratio of the first voids and the second voids.

5. The device according to claim 1, wherein
a ratio x of the first voids and a ratio y of the second voids satisfy the following formula,
$${λ}_{bonding portion} = {λ}_{metal} ( 1 - x ) ( 1 - y ) \geq 200 ,$$
the λ_{bonding portion} being a thermal conductivity of the bonding portion, and
the λₘₑₜₐₗ being a thermal conductivity of a metal bulk forming the metal sintered body.

6. The device according to claim 1, wherein
the first voids are disposed in a houndstooth pattern in the bonding portion, and
a ratio of the first voids is reduced in a region where stress and heat are concentrated in the bonding portion.

7. The device according to claim 1, wherein
the first void has a circular shape or a polygonal shape in a top view.

8. The device according to claim 1, wherein
a dimension of the first void is reduced in a region where stress and heat are concentrated in the bonding portion.

9. The device according to claim 1, wherein
the bonding portion contains any metal of Ag, Cu, Au, Ni, Al, and Pt.
